(19) United States
(12) Patent Application Publication
(10) Pub. No.: US 2008/0088370 A1
(43) Pub. Date: Apr. 17, 2008

(54) Method, apparatus and system for reducing noise from an amplifier

(76) Inventors: Seung-Bin You, Seongnam-si (KR); Chun-Kyun Seok, Seoul (KR)

Correspondence Address: HARNESS, DICKEY & PIERCE, P.L.C., P.O. BOX 8910, RESTON, VA, 20195, US

(21) Appl. No.: 11/889,417

(22) Filed: Aug. 13, 2007

(30) Foreign Application Priority Data
Aug. 23, 2006 (KR) 10-2006-0079718

(51) Int. Cl. H03F 3/217

(52) U.S. Cl. 330/251

(57) ABSTRACT

A digital amplifier, a noise reduction circuit and a method of reducing noise from an output signal of a digital amplifier are described in this disclosure. The digital amplifier includes a driving circuit for providing a driving signal, a filter for filtering the driving signal and providing the filtered driving signal to a resistive load connected between an output node and a reference node of the digital amplifier, a noise reduction circuit controlling the reference node to be in a floating state to reduce noise while the filtered driving signal provided to the load via the output node stabilizes.

### PRIORITY STATEMENT

This application claims the priority of Korean Patent Application No. 2006-79718, filed on Aug. 23, 2006, in the Korean Intellectual Property Office, the entire contents of which is incorporated herein by reference.

### BACKGROUND

1. Field of the Invention

Example embodiments relate to an amplifier and corresponding method. In particular, example embodiments relate to an amplifier and a method of reducing noise from an amplifier.

2. Description of the Related Art

Various conventional amplifiers have been used to amplify audio signals. These conventional amplifiers include class-A, class-B, class-AB and class-D amplifiers. Generally, class-D amplifiers have superior power efficiency characteristics as compared with the class-A, class-B and class-AB amplifiers.

Class-D amplifiers are commonly used in portable devices at least in part because of an increased emphasis that is generally placed on the size and weight of portable devices. For example, headphones associated with various portable audio players include class-D amplifiers.

FIG. 1 is a basic block diagram illustrating a conventional class-D amplifier 100, and FIGS. 2A-E illustrate a simplified example of the signal processing performed by each of the components of the class-D amplifier 100. The operation of the conventional class-D amplifier 100 is explained below referring to FIGS. 1 and 2A-E.

The class-D amplifier 100 includes a Pulse Width Modulation (PWM) signal generator 10, a class-D driving circuit 20, a low pass filter 30, a coupling capacitor C2, and a relay 40. FIG. 2A illustrates the PWM signal generator 10 receives a first signal 13 and a second signal 11. The first signal 13 is shown in FIG. 2A as a square wave. For example, the first signal 13 may be received from an internal or external clock. The second signal 11 received by the class-D amplifier 100 is referred to hereinafter as an audio input signal 11. In order to simplify the explanation, the received audio input signal 11 is illustrated in FIG. 2A as a sinusoidal wave. The PWM signal generator 10 processes the first signal 13 and the audio signal 11 and outputs a PWM signal 15 to the class-D driving circuit 20. The PWM signal 15 is shown in FIG. 2B, and the duty cycle of the PWM signal 15 is varied according to the received audio signal 11. The class-D driving circuit 20 amplifies the PWM signal 15 and provides the amplified signal 25 shown in FIG. 2C to the low pass filter 30. The low pass filter 30 averages the amplified signal 25, thereby reducing high frequency noise, and provides the filtered signal 31 to the coupling capacitor C2. The coupling capacitor C2 removes the DC voltage from the filtered signal 31 and outputs an output signal 33. The output signal 33 is provided to a speaker 150 via the relay 40. The relay 40 maintains an open state until operation of the class-D amplifier 100 is stable. Accordingly, the relay 40 reduces and/or eliminates the occurrence of pop-up noise generated by the class-D amplifier 100 being provided to the speaker 150, which has a resistance RL and is connected to the class-D amplifier 100. The speaker 150 is a speaker, for example, included in headphones for a portable audio device.

FIGS. 3A-C are timing diagrams illustrating an example of pop-up noise generated by a class-D amplifier 100, which is reduced and/or prevented from reaching the speaker 150 by the relay 40 of the class-D amplifier 100. Each of FIGS. 3A-C illustrates a voltage signal provided over a time duration including four states. The four states illustrated in FIGS. 3A-3C are an initial state P0, an initial output state P1, a mute state P2 and a normal operation state P3. The initial state represents an amount of time taken for a system including the class-D amplifier 100 to power-on or reset. For example, if the class-D amplifier 100 is included in a portable music device, the initial state P0 may correspond to the time taken for the portable music device to power-on in response to power being supplied to the portable music device. The initial output state P1 corresponds to a time duration used by the class-D amplifier 100 to respond to an input signal. For example, once an audio input signal AI or a mute signal MUTE is provided to the class-D amplifier 100, the class-D amplifier 100 stabilizes over the time duration of the initial output state P1. The mute state P2 corresponds to the time duration in which a mute signal is received by the class-D amplifier 100. For example, the mute signal MUTE may be received by the class-D amplifier 100 in response to a user input. The normal operation state P3 corresponds to the time duration in which an audio input signal is provided to the class-D amplifier 100 and the class-D amplifier 100 is providing an output corresponding to the audio input.

In FIG. 3A, an output voltage signal VA provided to the output node NA is illustrated as being substantially equal to a voltage VSS during the initial state P0. However, one skilled in the art will readily appreciate that the output voltage signal VA during the initial state P0, which corresponds to the power-up or reset of the class-D amplifier 100, is unstable. Further, one skilled in the art will readily appreciate that the voltage VSS may correspond to zero volts or a negative voltage rail, for example.

During the initial output state P1 shown in FIG. 3A, the output voltage signal VA provided to the output node NA begins to stabilize. In FIG. 3A, the voltage signal VA begins to rise from a voltage VSS to the reference voltage VR. The reference voltage VR shown in FIG. 3A is equal to one half of the sum of the voltage VSS and a supply voltage VDD, and is represented by Equation (1) shown below.
VR=(VDD+VSS)/2 (1)
The initial output state P1 corresponds to a time period required for an output signal of the digital amplifier 100 to stabilize in response to a mute signal received by the class-D driving circuit 20.

During the mute state P2 shown in FIG. 3A, the output voltage signal VA is maintained at reference voltage VR. For example, the low-pass filter 30 of the class-D amplifier 100 averages a one half duty ratio PWM signal provided by the class-D driving circuit 20 and provides an output signal having a relatively constant voltage approximately equal to the supply voltage VDD to the capacitor C2. The capacitor C2 functions to remove the DC component from the signal resulting in an output voltage VA having a substantially constant value equal to the reference voltage VR.

In FIG. 3A, a sinusoidal signal with a high voltage corresponding to the supply voltage VDD and a low voltage corresponding to the voltage VSS is shown in the normal operation state P3 to represent normal operation of the class-D amplifier 100. One skilled in the art will readily appreciate that the signal output during the normal operation state P3 would correspond to an input signal received by the PWM signal generator 10 of the class-D amplifier 100.

FIG. 3B is a timing diagram illustrating a reference voltage signal VB provided to reference node NB. FIG. 3B also illustrates the output voltage signal VA as a dotted line in the initial output state P1.

The reference voltage signal VB provided to the output node NB, like the output voltage signal VA shown in FIG. 3A, is illustrated at being substantially equal to a voltage VSS during the initial state P0. However, one skilled in the art will readily appreciate that the output voltage signal VA during the initial state P0, which corresponds to the power-up or reset of a class-D amplifier 100, is unstable.

During the initial output state P1 shown in FIG. 3B, the reference voltage signal VB provided to the reference node NB begins to stabilize. In particular, the voltage of the reference voltage signal VB begins to increase from the voltage VSS to the reference voltage VR. However, a comparison of the output voltage signal VA shown as the dotted line and the reference voltage signal VB in FIG. 3B illustrates the reference voltage signal VB reaches the reference voltage VR before the output voltage signal VA reaches the reference voltage VR.

During the mute state P2 and the normal operation state P3 shown in FIG. 3B, the reference voltage signal VB provided to the reference node NB is maintained at the reference voltage VR.

FIG. 3C is a timing diagram illustrating a difference between the output voltage signal VA and the reference voltage signal VB. As such, FIG. 3C is a resultant signal experienced by a load connected between the output node NA and the reference node NB.

Because both the output voltage signal VA and the reference voltage signal VB are unstable during the initial state P0, the value of the resultant signal VA-VB is shown as being equal to the voltage VSS during the initial state P0 for the sake of simplicity. The resultant signal VA-VB shown in the initial output state P1 of FIG. 3C represents pop-up noise. The pop-up noise occurs because the reference voltage signal VB provided to the reference node NB stabilizes quicker than the output voltage signal VA provided to the output node NA. During the mute state P2 of FIG. 3, the resultant signal VA-VB is maintained at the voltage VSS since both output voltage signal VA and the reference voltage signal VB are substantially equal to the reference voltage VR during this state. FIG. 3C shows the resultant signal VA-VB as being a sinusoidal wave with a high voltage value equal to the reference voltage VR and a low voltage value equal to a negative reference voltage −VR.

To avoid the pop-up noise from being transmitted to a load such as the speaker 150 shown in FIG. 1 connected between the output node NA and the reference node NB, the relay 40 is included in the class-D amplifier 100. As previously described, the relay 40 maintains an open state until operation of the class-D amplifier 100 is stable. As such, the pop-up noise shown in FIG. 3C occurring during the initial output state P1 is prevented from reaching the speaker 150.

Unfortunately, incorporating the relay 40 to reduce and/or eliminate pop-up noise from being provided to the speaker 150 increases the chip area required for the class-D amplifier 100.

Further, as described above, the conventional class-D amplifier 100 shown in FIG. 1 includes the coupling capacitor C2 for removing the DC voltage from the filtered signal 31. The coupling capacitor C2 is used to prevent high currents from flowing through the headphones and having the headphones be in a continuously on state. If the resistance RL of the speaker 150 is about 16-32 ohms, which is typical, the capacitance value of the coupling capacitor C2 is typically within a range of 100-470 μF. However, the physical size of a 100-470 μF coupling capacitor is prohibitively large and thus, inhibits the miniaturization of the conventional class-D amplifier 100 including one or more coupling capacitors.

Accordingly, the relay 40 and the coupling capacitor C2 inhibit the miniaturization of audio or video devices including class-D amplifiers.

### SUMMARY

Example embodiments are directed to a digital amplifier and a method of reducing noise from a digital amplifier.

An example embodiment provides a digital amplifier that includes a driving circuit configured to provide a driving signal; a filter configured to filter the driving signal and provide the filtered driving signal to a resistive load connected between an output node and a reference node; and a noise reduction circuit configured to control the reference node to be in a floating state to reduce noise while the filtered driving signal provided to the load via the output node stabilizes.

Another example embodiment of a digital amplifier includes a driving circuit configured to provide a driving signal; a filter configured to filter the driving signal and provide the filtered driving signal to a load connected between an output node and a reference node; a reference voltage generator configured to provide a reference voltage signal to a reference node; and a noise reduction circuit configured to cause the reference voltage signal provided to a reference terminal of a load via the reference node to be substantially equal to the filtered driving signal provided to an input terminal of the load via the output node for a delay time associated with a charging time of the filter.

Still another example embodiment provides a noise reduction circuit, which may be included in a digital amplifier. The noise reduction circuit includes a floating control signal generator and a floating controller. The floating control signal generator is configured to receive an activation signal and an input signal and generate a floating control signal based on the activation signal and the input signal. The activation signal relates to an activation or reset of the digital amplifier, and the input signal relates to a filtered driving signal output by a digital amplifier. The floating controller is configured to provide a reference voltage signal to a reference terminal of a load driven by the digital amplifier if the floating control signal is in a first state and cause the reference node to be in a floating state if the floating control signal is in a second state.

An example embodiment provides a method of reducing noise from an output signal of a digital amplifier. The method includes the steps of placing a reference node in a floating state for a stabilization time of a low pass filter of the digital amplifier; and releasing the reference node voltage from the floating state after the stabilization time.

Another example embodiment of a method for reducing noise from an output signal of a digital amplifier includes sustaining a reference node voltage in a high impedance state while a driving circuit of the digital amplifier is stabilized; and releasing the reference node voltage from the high impedance state once the digital amplifier is stabilized.

### BRIEF DESCRIPTION OF THE DRAWINGS

The above and other aspects and advantages of example will become more apparent by describing in detail example embodiments with reference to the attached drawings in which:

FIG. 1 is a basic block diagram illustrating a conventional class-D amplifier;

FIGS. 2A-E illustrate a simplified example of the signal processing performed by each of the components of the conventional class-D amplifier illustrated in FIG. 1;

FIGS. 3A-C are timing diagrams illustrating an example of pop-up noise generated by a conventional class-D amplifier;

FIG. 4 illustrates an example embodiment of an amplifier including a PWM driving circuit, a low-pass filter, a pop-up noise reduction circuit, a reference voltage generator 450 and a floating controller 470;

FIG. 5 illustrates an example embodiment of the PWM driving circuit and a low-pass filter, which may be included in a digital amplifier;

FIG. 6 illustrates an example configuration of a pop-up noise reduction circuit;

FIG. 7 illustrates an example configuration of the reference voltage generator and a floating controller;

FIG. 8 is a timing diagram illustrating the operation of the pop-up noise reduction circuit according to an example embodiment

FIGS. 9A-C are timing diagrams respectively illustrating an output signal provided to an output node of an amplifier, a reference signal provided to a reference node of the amplifier, and a resultant driving signal provided to a load connected between the output node and the reference node of the amplifier;

FIG. 10 is a flow chart illustrating a method of reducing noise from an output signal of an amplifier;

FIG. 11 illustrates an example configuration of a buffer and a floating controller; and

FIG. 12 illustrates an example configuration of the floating controller shown in FIG. 11.

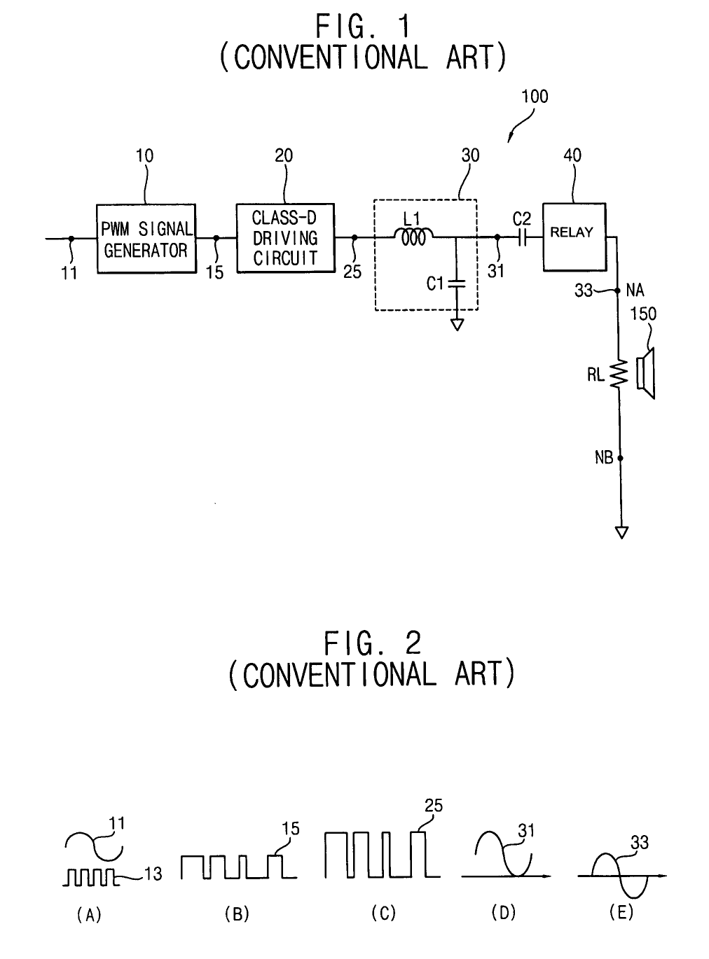

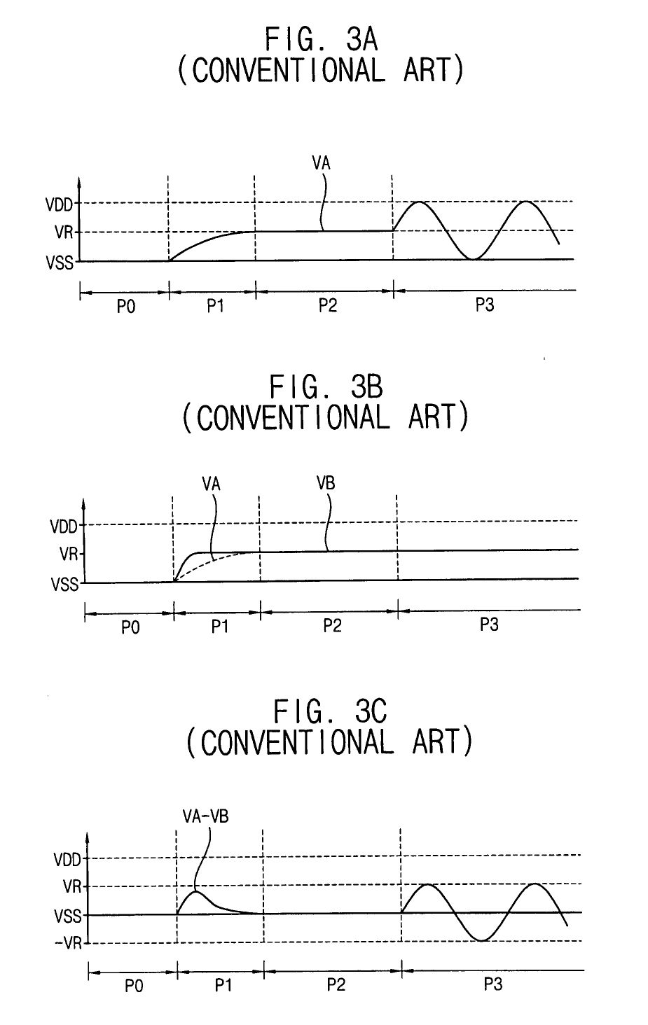

### DETAILED DESCRIPTION OF EXAMPLE EMBODIMENTS

Various example embodiments are now described more fully with reference to the accompanying drawings in which some example embodiments are shown. However, specific structural and functional details disclosed herein are merely representative for purposes of describing example embodiments, and one skilled in the art will appreciate that example embodiments may be embodied in many alternate forms and should not be construed as limited to only the embodiments set forth herein.

It will be understood that, although the terms first, second, etc. may be used herein to describe various components, these components should not be limited by these terms. These terms are only used to distinguish one component from another. For example, a first component could be termed a second component, and, similarly, a second component could be termed a first component, without departing from the scope of the example embodiments.

It will be understood that when a component is referred to as being “connected” or “coupled” to another component, it can be directly connected or coupled to the other component or intervening components may be present. In contrast, when a component is referred to as being “directly connected” or “directly coupled” to another component, there are no intervening components present. Other words used to describe the relationship between components should be interpreted in a similar manner (e.g., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items, unless the context clearly indicates otherwise.

Now, in order to more specifically describe example embodiments various embodiments are described in detail with reference to the attached drawings.

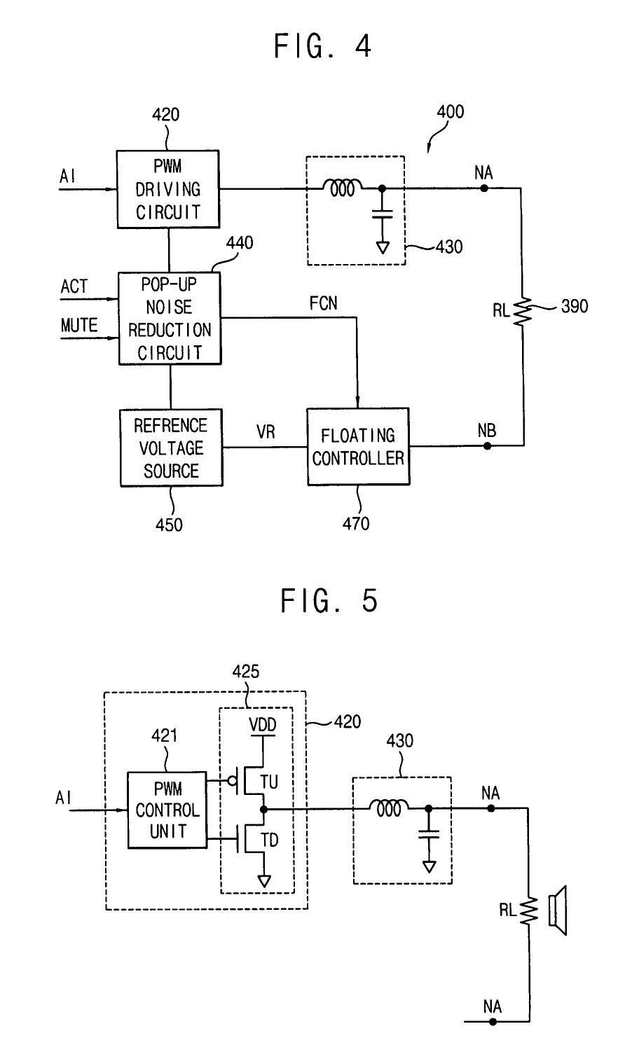

Referring to FIG. 4, an example embodiment of an amplifier 400 includes a PWM driving circuit 420, a low-pass filter 430, a pop-up noise reduction circuit 440, a reference voltage generator 450 and a floating controller 470. The amplifier 400 provides an output signal to an output node NA and a reference signal to a reference node NB. As shown in FIG. 4, one or more speakers 390 may be connected between the output node NA and the reference node NB. The output node NA of the amplifier 400 is the input node of the one or more speakers 390 having a load RL.

The PWM driving circuit 420 may be a class-D driving circuit. The PWM driving circuit 420 pulse width modulates and amplifies an input signal and outputs an amplified PWM signal representing the input signal. The input signal may be an audio input signal AI.

The amplified PWM signal is then provided to the low pass filter 430. The low pass filter 430 averages the amplified PWM signal reducing high frequency components of the signal such as noise, and outputs a filtered signal via the output node NA.

The pop-up noise reduction circuit 440 is configured to reduce and/or prevent pop-up noise. The pop-up noise reduction circuit 440 receives an activation signal ACT and a mute signal MUTE. The activation signal ACT is a signal provided following a reset operation or a power-up operation of the amplifier 400. For example, the activation signal ACT may be provided by a Power-On-Reset circuit. Power-On-Reset circuits are well-known in the art and thus, will not be discussed herein for the sake of brevity. The mute signal MUTE is a signal triggering an amplifier 400 to provide a constant output signal. For example, the mute signal MUTE may be provided to the amplifier 400 in response to a user input. Based on the received activation signal ACT and the mute signal MUTE, the pop-up noise reduction circuit 440 provides a floating control signal FCN to the floating controller 470. According to an example embodiment, the floating control signal FCN provided to the floating controller 470 by the pop-up noise reduction circuit 440 controls whether or not the reference node NB receives a reference voltage VR from the reference voltage generator 450 or is placed and/or maintained in a high impedance state.

The reference voltage generator 450 generates a reference voltage VR from a supply voltage VDD. For example, the reference voltage generator 450 generates a reference voltage VR having a voltage value between a high (e.g., maximum) voltage value of the output signal and a low (e.g., minimum) voltage value of the output signal; the output signal being the filtered signal provided to an input of the speaker 390 via the output node NA. The value of the reference voltage VR generated by the reference voltage generator 340 may be substantially constant. According to an example embodiment, the reference voltage VR is set at a desired value. The desired value may correspond to a median value between a high voltage value and a low voltage value of the output signal. For example, if the high voltage value of the output signal is about 5 volts and the low voltage value of the output signal is about 0 volts, the desired value is set to about 2.5 volts. The reference voltage VR generated by the reference voltage generator 450 is provided to the floating controller 470.

The floating controller 470 receives the reference voltage VR generated by the reference voltage generator 450 and the floating control signal FCN provided by the pop-up noise reduction circuit 440. The floating controller 470 controls whether or not the reference voltage VR provided by the a reference voltage generator 450 is provided to the reference node NB or if the reference node NB is maintained in a high impedance state, i.e., a floating state.

Still referring to FIG. 4, the amplifier 400 is connected to one or more speakers 390 having a resistance RL. The speakers 390 may be headphone speakers for a portable audio device. In particular, the output signal of the low pass filter 430 is provided to a first input of the one or more speakers via the output node NA (i.e., the input node of the one or more speakers 390). The reference signal generated by the reference voltage generator 450 is provided to a second input of the one or more speakers via the reference node NB or the reference node NB is maintained in a high impedance state based on an operation of the floating controller 470.

Further, as shown in FIG. 4, the amplifier 400 does not include coupling capacitors or a relay connected in series between the low-pass filter 430 and the load RL attached to the amplifier 400. Stated differently, the filtered, amplified pulse width modulated signal output by the low-pass filter 430 is provided directly from the low pass filter 430 to the one or more speakers 390 having the load RL. Still further, according to an example embodiment, the amplifier circuit 300 includes a pop-up noise reduction circuit 440 and a floating controller 470 for reducing and/or eliminating pop-up noise.

FIG. 5 illustrates an example embodiment of the PWM driving circuit 420 and the low-pass filter 430.

Referring to FIG. 5, the PWM driving circuit 420 includes a PWM control circuit 421 and a switching amplifier 425. The PWM control circuit 421 pulse width modulates a received audio input signal AI and outputs a PWM signal, via a first output and second output, to the switching amplifier 425. The example configuration of the switching amplifier 425 shown in FIG. 5 includes a PMOS transistor TU and an NMOS transistor TD connected in series between a supply voltage VDD and ground. In particular, the source of the PMOS transistor TU is connected to the supply voltage VDD; the gate of the PMOS transistor TU is connected to a first output signal of the PWM control circuit 421; and the drain of the PMOS transistor TU is connected to an input of the low-pass filter 430 and the source of the NMOS transistor TD. The source of the NMOS transistor TD is connected to the input of the low-pass filter 430 and the drain of the PMOS transistor TU; the gate of the NMOS transistor TD is connected to the second output of the PWM control unit 421; and the drain of the NMOS transistor TD is grounded. As such, the transistors of the switching amplifier 425 are driven by the PWM signal provided by the PWM control unit 421, thereby providing an amplified PWM signal.

The low-pass filter 430 shown in FIG. 5 includes an inductor and a capacitor. As previously indicated, the low-pass filter 430 averages the amplified PWM signal reducing high frequency components of the signal such as noise, and outputs an output signal to the output node NA. Specific configurations and operations of low-pass filters are well-known in the art and thus, will not be further discussed herein for the sake of brevity.

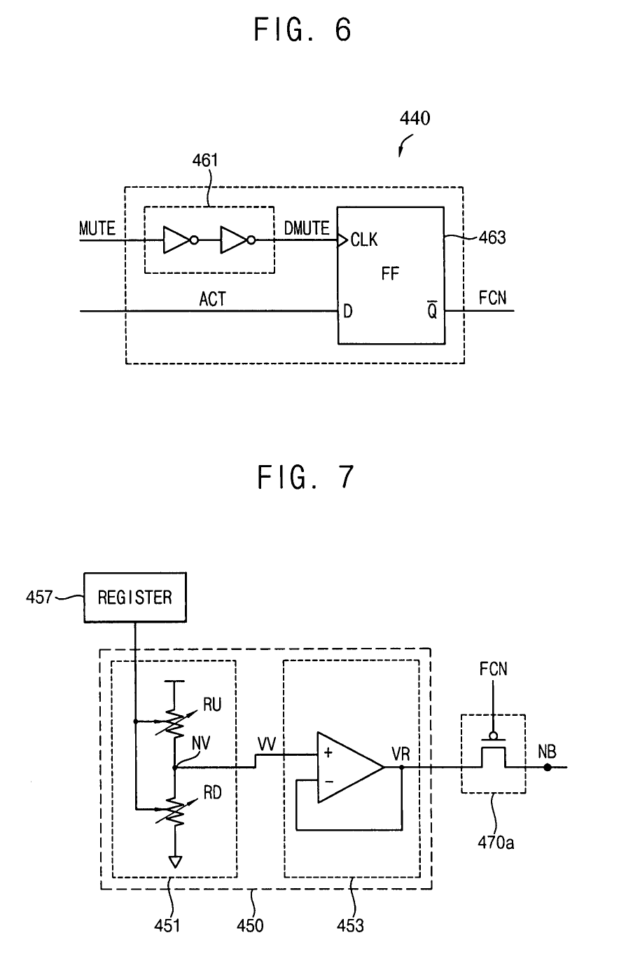

FIG. 6 illustrates an example configuration of a pop-up noise reduction circuit 440. The pop-up noise reduction circuit 440 includes a delay 461 and a D flip flop 463. As previously indicated, the mute signal MUTE is a signal triggering an amplifier 400 to provide a constant output signal. The mute signal MUTE received by the pop-up noise reduction circuit 440 is provided to the delay 461, which delays the mute signal MUTE a desired and/or predetermined amount of time and provides a delayed mute signal DMUTE to a clock input terminal of the D flip flop 463. The pop-up noise reduction circuit 440 also receives an activation signal ACT, which is a signal provided following a reset operation or a power-up operation of the amplifier 400. As previously described, the activation signal ACT may be provided by a Power-On-Reset circuit. The activation signal ACT is provided to the D input terminal of the D flip flop 463. Based on the received delayed mute signal DMUTE and the activation signal ACT, the D flip flop 463 outputs a floating control signal FCN to the floating controller 470. An example operation of the pop-up noise reduction circuit 440 is described in greater detail later with respect to the timing diagram of FIG. 8.

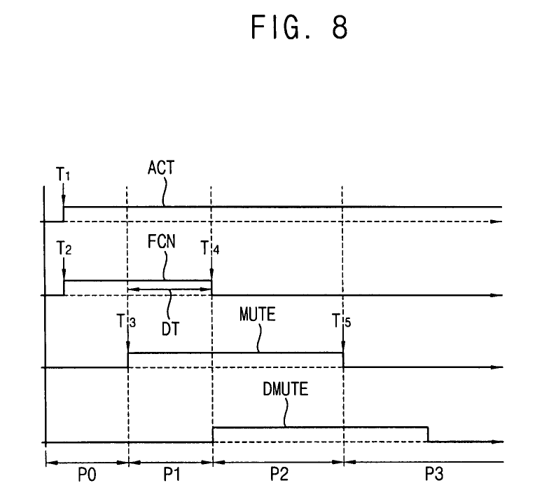

FIG. 7 illustrates an example configuration of the reference voltage generator 450 and the floating controller 470.

Referring to FIG. 7, the example configuration of the reference voltage generator 450 includes a voltage divider 451 and an analog buffer 453 (also referred to as a unit gain amplifier or voltage follower). The voltage divider 451 generates a voltage divider voltage VV from the supply voltage VDD. The voltage divider 451 includes a first variable resistor RU and a second variable resistor RD connected in series between a supply voltage VDD and ground. The first variable resistor RU and the second variable resistor RD are connected via a voltage divider node NV of the voltage divider 341, and a voltage divider voltage VV at the voltage divider node NV is provided to the analog buffer 453. A resistance value of the first variable resistor RU may be controlled based on a first control signal OSCU, and a resistance value of the second variable resistor RD is controlled based on a second control signal OSCD. Each of the first control signal OSCU and second control signal OSCD may be based on information stored in a register 457. The voltage divider voltage VV of the voltage divider 341 is calculated as shown below in equation 2. For example, the information stored in the register 457 may be a user input voltage value, information associated with the load RL of the one or more speakers 390, a table indicating the relationship between the first and second control signals OSCU and OSCD and resistance values of the first and second variable resistors RU and RD, specifications including manufacturing tolerances of the actual components of the amplifier circuit 400, etc.

$$VV = \frac{RD}{RU + RU} \times VDD \qquad ( 2 )$$

For example, if the supply voltage VDD is about 5.0 volts and the resistance values of the first variable resistor RU and the second variable resistor RD are both approximately 1 kohms, equation 2 would provide a voltage divider voltage VV of approximately 2.5 volts. However, due to manufacturing tolerances, etc., the actual components in the voltage divider may vary and thus, information stored in the register 347 controlling the first control signal OSCU and the second control signal OSCD may be used to further control the voltage divider voltage VV output by the voltage divider 341. As previously indicated, the voltage divider voltage VV is then stabilized by the analog buffer 453.

The analog buffer 453 operates to stabilize the voltage divider voltage VV and provide the reference voltage VR. As shown in FIG. 7, the analog buffer 453 receives the voltage divider voltage VV from the voltage divider 451, stabilizes the voltage divider voltage VV, and provides the stabilized voltage divider voltage VV to the floating controller 470. The stabilized voltage divider voltage is referred to hereinafter as the reference voltage VR. The analog buffer 453 includes an operational amplifier and stabilizes the voltage divider voltage VV to provide the reference voltage VR by feeding back the buffered voltage divider voltage to an inverting input of the operation amplifier. The analog buffer 453 provides the reference voltage to the floating controller 470.

According to an example embodiment, the floating controller 470 is a switching device. The example configuration of the switching device is shown in FIG. 7 as a floating controller 470a. The floating controller 470a is a PMOS transistor. In particular, the gate of the PMOS transistor receives the floating control signal FCN from the pop-up noise reduction circuit 440, the source of the PMOS transistor receives the reference voltage VR from the reference voltage generator 450 and the drain of the PMOS transistor is electrically connected to the reference node NB.

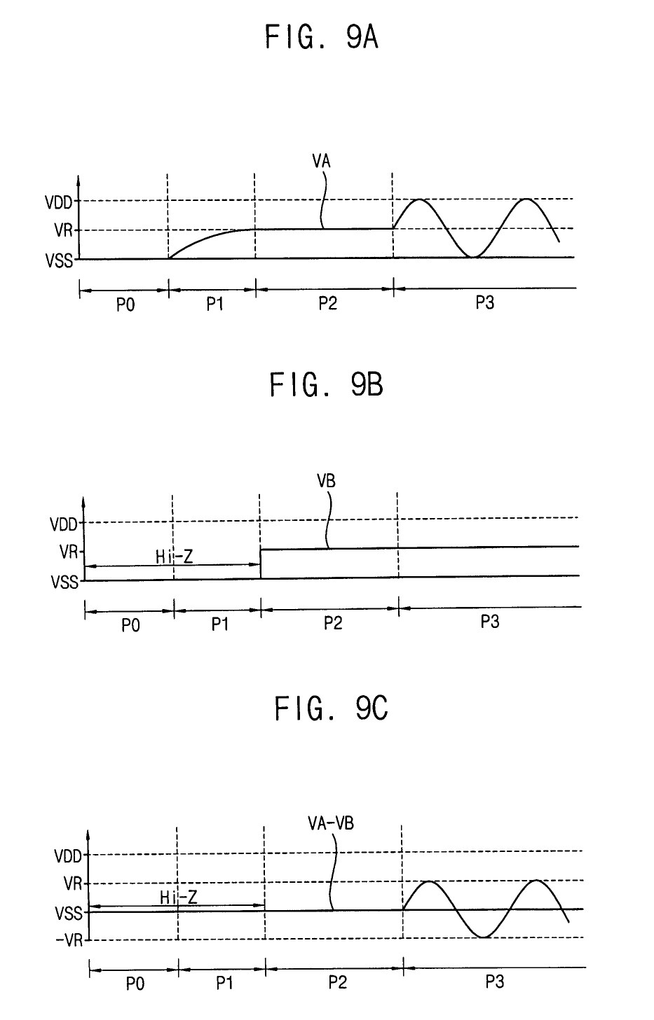

The operation of the various components of the amplifier 400 will now be described with reference to the timing diagrams of FIGS. 8 and 9.

FIG. 8 is a timing diagram illustrating the operation of the pop-up noise reduction circuit 400 according to an example embodiment. The timing diagram of FIG. 8 illustrates an example activation signal ACT, floating control signal FCN, mute signal MUTE and a delayed mute signal DMUTE signal over a time duration including four states.

The four states illustrated in FIG. 8 are an initial state P0, an initial output state P1, a mute state P2 and a normal operation state P3. The initial state P0 in FIG. 8 represents an amount of time taken for a system including the amplifier 400 to power-on or reset. For example, if the amplifier 400 is included in a portable music device, the initial state P0 corresponds the time taken for the portable music device to turn on in response to power being supplied to the portable music device. The initial output state P1 corresponds to a time duration used by the amplifier 400 to respond to an input. For example, once an audio input signal AI or a mute signal MUTE is provided to the amplifier 400, the amplifier 400 stabilizes over the time duration of the initial output state P1. The mute state P2 corresponds to the time duration in which a mute signal is received by the amplifier circuit 400. For example, the mute signal MUTE may be received by the amplifier circuit in response to a user input. The normal operation state P3 corresponds to the time duration in which an audio input signal is provided to the amplifier circuit 400 and the amplifier circuit is providing an output corresponding to the audio input.

In FIG. 8, the activation signal ACT transitions from a low state to a high state at a time point T1 in the initial state P0. The floating control signal FCN transitions from a low state to a high state at a time point T2 in the initial state P0. For example, the transition from the low state to the high state of the activation signal ACT and the floating control signal FCN may be in response to a device including the amplifier 400 receiving power. In particular, the high state of the activation signal ACT indicates the device or system including the amplifier circuit 400 is activated, and the high state of the floating control signal FCN may be a default state of the floating control signal FCN upon activation of the amplifier 400. In FIG. 8, the time point T2 corresponds to the time point T1. Both the mute signal MUTE and the delayed mute signal DMUTE are shown as a low state during the initial state P0 shown in FIG. 8.

As shown in the example configuration of the pop-up noise reduction circuit 440 of FIG. 6, the mute signal MUTE is received by the delay 461 of the pop-up noise reduction circuit 440 and the activation signal ACT is received by the D flip-flop 463 of the pop-up noise reduction circuit 440. In particular, the delay 461 delays the mute signal MUTE for a predetermined and/or desired time and provides the delayed mute signal DMUTE to the clock input terminal of the D flip-flop 463. The D input terminal of the D flip-flop 463 receives the activation signal ACT and the inverting output of the D flip-flop 463 outputs the floating control signal FCN based on the delayed mute signal DMUTE and the activation signal act.

As shown in the timing diagram of FIG. 8, both the activation signal ACT and the floating control signal FCN are maintained in a high state during the remainder of the initial state P0 and the initial output state P1. In FIG. 8 at the beginning of the initial output state P1 identified by time point T3, the mute signal MUTE received by the delay 461 of the pop-up noise reduction circuit transitions from a low state to a high state. The delay 461 delays the mute signal MUTE for a desired and/or predetermined time duration DT and provides the delayed mute signal DMUTE to the clock input terminal of the D flip flop 463. The desired and/or predetermined time duration DT corresponds to an amount of time required for outputs of the amplifier circuit 400 to stabilize. In response to the receiving the rising edge of the delayed mute signal DMUTE, the floating control signal FCN output by the D flip-flop 463 transitions from a high to low state. For example, since the D input terminal of the D flip-flop 463 is receiving an activation signal ACT in a high state when the rising edge of the DMUTE signal is received at the clock input terminal of the D flip-flop 463, the floating control signal FCN output from the inverting output terminal of the D flip-flop 463 transitions from the default high state to a low state at a time point T4.

During the mute state P2 and the normal operation state P3, the activation signal ACT remains in a high state and the floating control signal FCN remains in a low state. Following the mute state P2, the mute signal MUTE transitions from a high state to a low state at the time point T5. Accordingly, the delayed mute signal DMUTE transitions from the high state to low state a time duration DT after time point T5.

FIGS. 9A-C are timing diagrams respectively illustrating an output signal VA provided to output NA of the amplifier 400, a reference signal VB provided to the reference node NB of the amplifier 400, and a resultant driving signal VA-VB provided to the speakers 390 connected between the output node NA and the reference node NB of the amplifier 400. Similar to FIG. 8, each of the timing diagrams FIGS. 9A-C illustrate a time duration including the initial state P0, the initial output state P1, the mute state P2 and the normal operation state P3.

In FIG. 9A, the output signal VA provided to a output node NA is illustrated as being substantially equal to a voltage VSS during the initial state P0. However, one skilled in the art will readily appreciate that the output signal VA during the initial state P0, which corresponds to the power-up or activation of the amplifier 400, is unstable. Further, one skilled in the art will readily appreciate that the voltage VSS may correspond to zero volts or a negative voltage rail, for example.

During the initial output state P1 shown in FIG. 9A, the output signal VA provided to the output node NA begins to stabilize. In particular, the voltage signal VA begins to rise from the voltage VSS to the reference voltage VR. In FIG. 3A, the reference voltage VR is equal to one half of the sum of the voltage VSS and a supply voltage VDD, as shown in Equation 3 below.
VR=(VDD+VSS)/2 (3)
As previously indicated, the initial output state P1 corresponds to a time period required for an output signal of the digital amplifier 100 to stabilize in response to a mute signal received by the PWM driving circuit 420.

During the mute state P2, the output signal VA is maintained at reference voltage VR. In particular, the low-pass filter 430 averages the one half duty ratio PWM signal provided by the PWM driving circuit 420 and provides an output signal VA having a relatively constant voltage approximately equal to the reference voltage VR to the output node NA.

In FIG. 9A, a sinusoidal signal with a high voltage corresponding to the supply voltage VDD and a low voltage corresponding to the voltage VSS is shown during the normal operation state P3 to represent normal operation of the digital amplifier 100. One skilled in the art will readily appreciate that the signal output during the normal operation state P3 would correspond to an input signal received by the PWM driving circuit 420.

FIG. 9B is a timing diagram illustrating a reference signal VB provided to reference node NB. As shown in FIGS. 4 and 7, the reference node NB is connected to the floating controller 470 and the example configuration of the floating controller 470a, respectively. As previously described with respect to FIG. 7, the floating controller 470a is a PMOS transistor having a gate receiving the floating control signal FCN, a source receiving the reference voltage VR and a drain connected to the reference node NB. According to the example configuration of the floating controller 470a shown in FIG. 7 and the timing diagram of FIG. 8, the PMOS transistor provides the reference voltage VR to the reference node NB when the floating control signal is in a low state during the mute state P2 and the normal operating state P3. Further, the floating control signal is in a high state during the initial state P0 and the initial output state P1 as shown in FIGS. 9A-C. Accordingly, the PMOS transistor of the floating controller 470a is open during the initial state P0 and the initial output state P1 and thus, the output node NB is in a high impedance state Hi-Z during the initial state P0 and the initial output state P1 as shown in the timing diagram of FIG. 9B. The PMOS transistor of the floating controller 470a is closed during the mute state P2 and the normal operation state and thus, the reference voltage VR is provided to the reference node NB.

FIG. 9C is a timing diagram illustrating a difference between the output signal VA and the reference signal VB. As such, FIG. 9C is the resultant signal experienced by the load connected between the output node NA and the reference node NB. Because, the voltage signal VB is in a high impedance Hi-Z state, i.e., a floating state, during the initial state P0 and the initial output state P1, the value of the reference signal VB is equal to the value of the output signal VA during the initial state P0 and the initial output state P1, thereby reducing and/or preventing pop-up noise.

However, as previously discussed with respect to the timing diagrams of FIGS. 9A-C, when the floating control signal FCN transitions from the high state to the low state at the beginning of the mute state P2, the PMOS transistor closes and provides the reference voltage VR to the reference node NB and thus, the reference node NB is no longer in a high impedance state Hi-Z. Accordingly, during the mute state P2, the resultant signal VA-VB is substantially constant and equal to VSS. Further, during the normal operation state P3, the resultant signal VA-VB is shown in FIG. 9C as a sinusoidal signal with a high voltage value equal to the reference voltage VR and a low voltage value equal to a negative value of the reference voltage −VR. One skilled in the art that the sinusoidal signal shown in the normal operating state P3 of FIG. 9C as the resultant signal VA-VB is used for simplicity, but the signal output during the normal operating state P3 would correspond with an input signal provided to the PWM driving circuit 420.

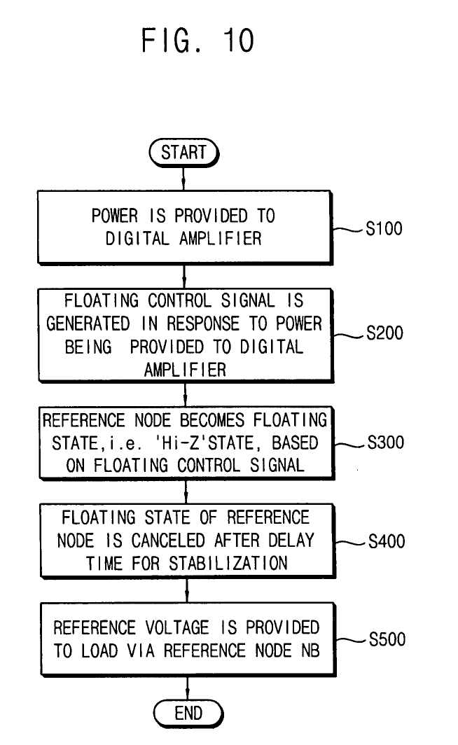

FIG. 10 is a flow chart illustrating a method of reducing noise from an output signal of a digital amplifier 400.

In step S100, power is provided to the digital amplifier. In response to power being provided to the digital amplifier 400, the activation signal ACT and mute signal MUTE are provided to the pop-up noise reduction circuit 440. Power is provided to the digital amplifier 400 during activation and a reset operation, for example. In step S200, a floating control signal FCN is generated by the pop-up noise reduction circuit 440. The floating control signal FCN causes a reference node NB to be in a floating state Hi-Z in step S300. In particular, the floating control signal is based on the received activation signal ACT and mute signal MUTE as previously described with respect to the timing diagram of FIG. 8. The reference node NB is maintained in the floating state for a delay time DT, which may correspond to the stabilization time of the low pass filter 430 of the digital amplifier 400, for example. In step S400, the floating state of the reference node is cancelled after the output signal of the digital amplifier 400 stabilizes. For example, the floating control signal FCN transitions from a first state to a second state after a delay time DT. A reference voltage VR is then provided to a load via the reference node NB in step S500.

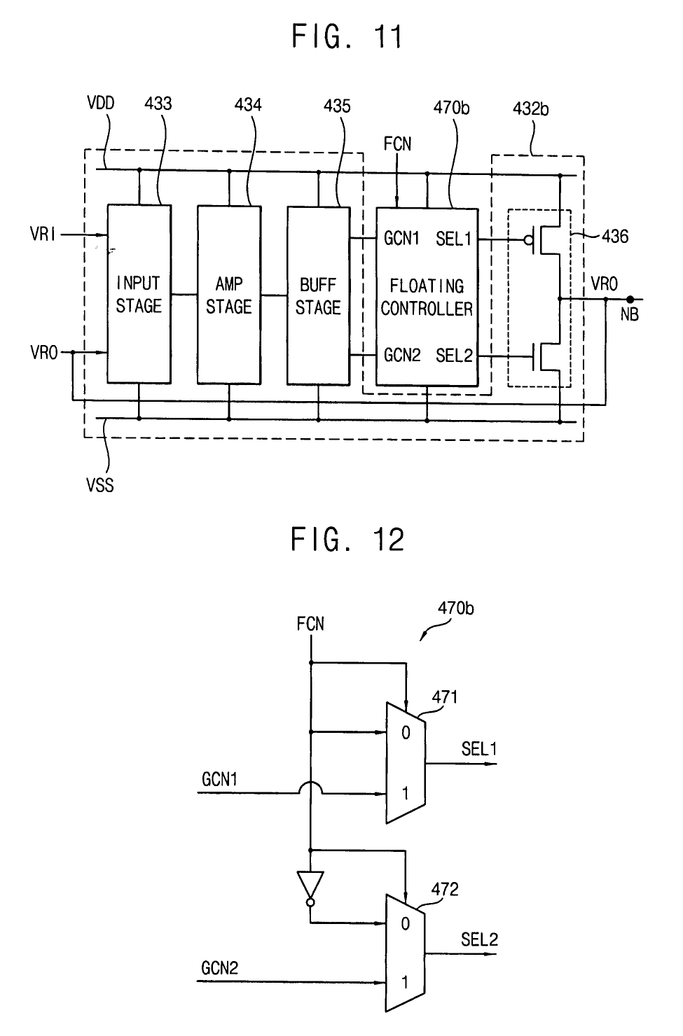

FIG. 11 illustrates another example configuration of a buffer 432b and a floating controller 470b.

The buffer 432 shown in FIG. 11 includes an input stage 433, an amplifier stage 434, a first buffer stage 435 and a second buffer stage 436. Each of the input stage 433, the amplifier stage 434, the first buffer stage 435 and the second buffer stage 436 are connected between the supply voltage VDD and the voltage VSS, which may correspond to zero volts or a negative voltage rail, for example. A first input of the input stage 433 receives an input voltage VR1, and the second input of the input stage 433 receives a feedback voltage VR0 output by the second buffer stage 436. The input stage 433, amplifier stage 434 and first buffer stage 435 are well-known known in the art and thus, the specifics of these stages will not be discussed herein for the sake of brevity.

As shown in FIG. 11, the first buffer stage 435 provides a first gate control signal GCN1 and a second gate control signal GCN2 to the example configuration of the floating controller 470b. The floating controller 470b also receives the floating control signal FCN from the pop-up noise reduction circuit 440 previously described with respect to FIG. 6.

An example configuration of the floating controller 470b is shown in FIG. 12. Referring to FIG. 12, the floating controller 470b includes a first selector 471, a second selector 472 and an inverter 473. An activation terminal of both the first selector 471 and the second selector 472 receive the floating control signal FCN. For example, both the first selector 471 and the second selector 472 may be configured such that if the floating control signal FCN is in a high state, both the first selector 471 and the second selector 472 are deactivated. According to the example configuration shown in FIG. 12, both the first selector 471 and the second selector 472 are activated if the floating control signal FCN is in a low state. Further, a first input terminal of the first selector 471 receives the floating control signal FCN and the second input terminal of the first selector 471 receives the first gate control signal GCN1 from the first buffer stage 435. According to the configuration shown in FIG. 12, if the floating control signal FCN is in a low state, the first selector 471 outputs a selection signal SEL1. The first input terminal of the second selector 472 receives the floating control signal FCN after the floating control signal FCN passes through the inverter 473. Accordingly, the first input of the second selector 472 receives a signal inverse to the signal received by the first input of the first selector 471. The second input terminal of the second selector 472 receives the second gate control signal GCN2 from the first buffer stage 435. Accordingly, if the floating control signal FCN is in a low state, the second selector outputs a second selection signal SEL2. Both the first selection signal SEL1 and the second selection signal SEL2 are provided to the second buffer stage 436 of the buffer 432b shown in FIG. 11

Referring back to FIG. 11, the second buffer stage includes a PMOS transistor and an NMOS transistor. The PMOS transistor and the NMOS transistor are connected in series between the power supply voltage VDD and the voltage VSS. The gate of the PMOS transistor receives the first selection signal SEL1 and the gate of the NMOS transistor receives the second selection signal SEL2. According to the example embodiment of the buffer 432b and the floating controller 470b shown in FIGS. 11 and 12, if the floating control signal FCN is in a low state, the first selection signal SEL1 causes the PMOS transistor to allow current to flow from the source to drain of the transistor and the second selection signal SEL2 causes the NMOS transistor to allow current to flow from the source to drain of the transistor and thus, a reference voltage VR is provided to the reference node NB. Alternatively, if the floating control signal FCN is in a high state, the first selection signal SEL1 and the second selection signal SEL2 respectively cause the PMOS and NMOS transistors to remain in an open state. When both the PMOS transistor and the NMOS transistor are in an open state, current does not pass through the transistors and the reference node is in a high impedance, i.e., floating, state.

While this invention has been particularly shown and described with reference to example embodiments of the present invention, it will be understood by those skilled in the art that various changes in form and details may be made therein without departing from the spirit and scope of the invention.

What is claimed is:

1. A digital amplifier comprising:
a driving circuit configured to provide a driving signal;
a filter configured to filter the driving signal and provide the filtered driving signal to a resistive load connected between an output node and a reference node; and
a noise reduction circuit configured to control the reference node to be in a floating state to reduce noise while the filtered driving signal provided to the load via the output node stabilizes.

2. The digital amplifier of claim 1, further comprising:
a reference voltage generator configured to provide a reference voltage; and
the noise reduction circuit including,
a floating control signal generator configured to receive an activation signal and an input signal and generate a floating control signal based on the activation signal and the input signal, the activation signal relating to one of an activation and reset of the digital amplifier and the input signal relating to the filtered driving signal, and
a floating controller configured to control the reference node to be in the floating state if the floating control signal is in a first state and provide the reference voltage to the load via the reference node if the floating control signal is in a second state.

3. The digital amplifier of claim 2, wherein the input signal is one of a mute signal triggering the filtered driving signal to be a relatively constant value and an audio input signal triggering the filtered driving signal to be an amplified version of the audio input signal.

4. The digital amplifier of claim 2, wherein the floating control signal generator includes
a delay configured to delay the input signal a time duration; and
a flip flop configured to receive the delayed input signal and the activation signal and provide the floating control signal, the flip flop providing the floating control signal in a first state until a rising edge of the delayed input signal is detected and providing the floating control signal in a second state based on the activation terminal after the rising edge is detected.

5. The digital amplifier of claim 2, wherein the floating controller is a switch configured to prevent the reference voltage provided by the reference voltage generator from reaching a reference node if the floating control signal is in the first state and pass the reference voltage to the reference node if the floating control signal is in the second state.

6. The digital amplifier of claim 5, wherein the switch is a PMOS transistor, the first state is a high state and the second state is a low state.

7. The digital amplifier of claim 2, wherein the floating controller comprises:
a first selector configured to output a first selection signal, the first selector having an activation terminal receiving the floating control signal to activate the first selector, a first input terminal receiving the floating control signal and a second input terminal receiving a first gate control signal;
an inverter configured to receive and invert the floating control signal; and
a second selector configured to output a second selection signal, the second selector having an activation terminal receiving the floating control signal to activate the second selector, a first input terminal receiving the inverted floating control signal and a second input terminal receiving a second gate control signal,
the first selection signal and the second selection signal being output to the reference voltage generator to control a value of the reference voltage provided by the reference voltage generator.

8. The digital amplifier of claim 1, wherein the driving circuit is a Class-D amplifier.

9. The digital amplifier of claim 1, wherein the noise reduction circuit does not include a relay.

10. The digital amplifier of claim 1, wherein the filtered driving signal is provided directly from the filter to the load.

11. The digital amplifier of claim 1, wherein the load includes at least one speaker.

12. A digital amplifier comprising:
a driving circuit configured to provide a driving signal;
a filter configured to filter the driving signal and provide the filtered driving signal to a load connected between an output node and a reference node;
a reference voltage generator configured to provide a reference voltage signal to a reference node; and
a noise reduction circuit configured to cause the reference voltage signal provided to a reference terminal of a load via the reference node to be substantially equal to the filtered driving signal provided to an input terminal of the load via the output node for a delay time associated with a charging time of the filter.

13. A noise reduction circuit for a digital amplifier comprising:
a floating control signal generator configured to receive an activation signal and an input signal and generate a floating control signal based on the activation signal and the input signal, the activation signal relating to one of an activation and reset of the digital amplifier and the input signal relating to a filtered driving signal output by the digital amplifier; and
a floating controller configured to provide a reference voltage signal to a reference terminal of a load driven by the digital amplifier if the floating control signal is in a first state and cause the reference node to be in a floating state if the floating control signal is in a second state.

14. A method of reducing noise from an output signal of a digital amplifier, comprising:
placing a reference node in a floating state for a stabilization time of a low pass filter of the digital amplifier; and
releasing the reference node voltage from the floating state after the stabilization time.

15. The method of claim 14, further comprising:
providing power to the digital amplifier in response to one of activation and reset of the digital amplifier;
the placing step causing the reference node voltage to be in the floating state in response to the power provided to the digital amplifier.

16. The method of claim 14, further comprising:
providing a relatively constant voltage to as the reference node voltage once the releasing step releases the reference node voltage from the floating state.

17. A method of reducing noise from an output signal of a digital amplifier, comprising:
sustaining a reference node voltage in a high impedance state while a driving circuit of the digital amplifier is stabilized; and
releasing the reference node voltage from the high impedance state once the digital amplifier is stabilized.
